(19) United States
(12) Patent Application Publication
(10) Pub. No.: US 2008/0260013 A1
(43) Pub. Date: Oct. 23, 2008

(54) Equalization with Selection of Samples

(76) Inventor: Markku Heikkila, Oulu (FI)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(21) Appl. No.: 11/792,195

(22) PCT Filed: Dec. 30, 2004
(86) PCT No.: PCT/IB2004/004307

§ 371 Date: Mar. 25, 2008

(51) Int. Cl. H03H 7/30

(52) U.S. Cl. 375/229

(57) ABSTRACT

A method is shown for equalizing signals transmitted via at least one transmission antenna and received by at least one reception antenna (2,4). To reduce filter complexity, chip-samples of the received signals are selected such that only one sample per chip is selected for each filter (30, 32; 34, 36).

### FIELD OF THE INVENTION

The invention relates in general to a method for equalizing signals, with transmitting signals via at least one transmission antenna, receiving the signals with at least two reception antennas, sampling the signals taking at least two samples per symbol or chip, and equalizing the received signals within filters assigned to a respective transmission antenna.

The invention further relates in general to a system for transmitting and equalizing signals with at least one transmission antenna arranged for transmitting signals, at least one reception antenna each arranged for receiving chip-samples of the transmitted signals, and equalizing means for filtering the received signals comprising filters assigned to a respective transmission antenna.

The invention also relates in general to a device for receiving and equalizing signals with at least one reception antenna arranged for receiving chip-samples of transmitted signal from at least one transmission antenna, and equalizing means for filtering each of the received signals comprising filters assigned to respective transmission antenna.

The invention relates in general also to a computer program and a computer program product for equalizing signals, the program comprising instructions operable to cause a processor to receive within each of at least one reception antenna chip-samples of a transmitted signal from at least one transmission antenna, and to equalize each of the received signals within filters assigned to a respective transmission antenna.

The invention further relates to the use of such a method, system, device, computer program or computer program product.

### BACKGROUND

In general, mobile communication systems suffer from distorted received signals due to multipath propagation generated on an air interface, in particular, when data is transmitted at high speed. The multipath propagation may cause a channel delay spread larger than zero. For instance, in CDMA or WCDMA systems, the multipath propagation may cause transmitted chips to overlap at the receiver, which may cause multiple access interference. For example, the spreading codes that were orthogonal at the transmitter may become non-orthogonal when they have propagated over a channel that has a delay spread larger than zero. The quality of the communication system may be undesirably degraded in case the distortion in the received signal is not compensated for during equalization at the receiver.

In order to provide high speed data transmission without service quality degradation, various signal transmission diversity techniques are employed. One possible transmission diversity technique is space diversity, which may, for example, be used for channels with small delay spread and channels with a low Doppler-Frequency spread, such as a so-called “pedestrian channel”. Using space diversity in general requires more than one transmission and/or reception antenna. When applying space diversity during transmission, the same signal is transmitted through at least two different transmission antennas.

For third generation transmission protocols, a space-time transmit diversity (STTD) technique has been employed. This type of diversity transmission may apply an open-loop mode transmission antenna diversity. STTD is a technique for obtaining a diversity gain through space-time coding. The space-time coding may be based upon a channel coding technique commonly applied on a time axis framework, but being extended into a spatial domain. Space diversity gain as well as time diversity gain may be obtained by performing coding among the transmitted symbols, respectively, through each of the transmission antennas.

Since each transmission antenna of a STTD transmission system needs to be equalized in the receiver, parallel equalizers for each transmit antenna need to be provided. For instance, with two transmission antennas, two parallel equalizer filters are required, which causes significant increase in complexity of the filter structure, when compared to an equalizer designed for a single-antenna transmission.

Another transmission protocol known is the high speed downlink package access (HSDPA) transmission protocol. For systems applying this protocol, equalizers are used as well for the transmission antennas. HSDPA transmission provides high rate data connections that may utilize also 16-QAM modulation, which is known to be sensitive to channel effects. Typically, only one transmission antenna is used for HSDPA, while one or several reception antennas may be used in the terminal receiver. However, STTD has been included into the HSDPA downlink transmission protocol as one option for transmitting data. Therefore, more than one equalizer required for equalizing the transmitted signals needs to be provided within the receiving system.

Therefore, one technical problem lies in the increased implementation effort when multiple transmission antennas are used. The costs for implementing a receiver is increased due to the increased amount of equalizers required. The filtering complexity suitable for HSDPA products is increased. The typical multiplication rate is increased, e.g. from 1.3 GHz to 2.6 GHz for equalizer finite impulse response (FIR) filter operation alone. Moreover, the filter tap solver complexity compared to equalizers which are designed for single-antenna HSDPA transmission needs to be increased.

### SUMMARY OF THE INVENTION

To overcome the above-mentioned problems, embodiments of the invention provide a method for equalizing signals, with transmitting signals via at least one transmission antenna, receiving within each of at least one reception antenna chip-samples of the transmitted signals, equalizing the received signals within filters assigned to a respective transmission antenna, which is characterized by filtering selectively the chip-samples of the received signals within filters assigned to the respective transmission antenna such that only one sample per chip is selected for filtering within the respective filters.

The received signal can be sampled taking at least two samples per chip. The samples can be equalized within filters assigned to a respective transmission antenna. More than one transmission antenna, in particular at least two transmission antennas is, also proposed.

According to embodiments, transmitting signals via at least two transmission antennas is provided. Reconfiguring equalizer filters arranged for at least two samples per chip and for 1-antenna transmission into equalizer filters arranged for at least 2-antenna transmission and filtering selectively the chip-samples of the received signals is also provided. The equalizer filters arranged for single antenna transmission with two chips per sample can be reconfigured into equalizer filters for at least 2-antenna transmission with selective filtering within the corresponding filters, as provided by embodiments.

The inventive method allows achieving nearly the same performance as a conventional STTD equalizer using two samples per chip. Multiplication rates of about 1.3 GHz are still possible. The inventive structure and method halves the filtering complexity and the filters used for equalization of 1-antenna transmission of a HSDPA receiver may easily be applied within STTD transmission, if required.

According to the inventive method, the filtering of the received signal can be done by selecting only one sample per chip per reception antenna. The selected samples may be received via any one of the reception antennas. For each of the transmission antennas the inventive method can provide dedicated equalizers. The dedicated equalizers can comprise filters adapted to the corresponding transmission antennas. The selected samples can be provided to the filters for each transmission antenna. Which sample of which reception antenna to choose for filtering can be decided for each equalizer, selectively.

For example, the filter may use different chip-samples from different reception antennas. For example, assuming that two samples per chip are available from the received signal, an equalizer assigned to the first transmission antenna may use only even (i.e. the first) chip-samples from reception antenna one, and only odd (i.e. the second) chip-samples from reception antenna two. The same may be applied to the equalizer assigned to the second transmission antenna. Applying the inventive method may provide compensating unfavourable sample-timing in one of the antennas by favourable sample-timing in the other antenna. The overall loss compared to two-samples-per-chip-filtering can be reduced.

Embodiments provide receiving the transmitted signal within at least two reception antennas. Further embodiments provide filtering selectively the chip-samples such that the used chip-samples are chosen from the reception antennas in an alternating order. For instance, first chip-samples may be filtered by filters connected to a first reception antenna and second chip-samples may be filtered by filters connected to a second reception antenna. This may be alternated, e.g. during the next time slot interval. The filters connected to the first and the second reception antennas may be dedicated filters for respective transmission antennas. Insofar, each selected sample from a certain reception antenna can be applied in all filters for all transmit antennas.

Other embodiments provide filtering selectively the chip-samples so that the chip-samples are chosen from the reception antenna based on the relative energy of the desired signal component in the received signal. The samples to be used from the reception antenna may be selected by comparing the total energy of their estimated channel vectors. This can be done either by taking into account a channel vector corresponding to a single transmit antenna, or by taking into account channel vectors from all transmit antennas. The energy driven selection can, for example, be based on which chip sample provides higher signal energy. This can also be based on energy of an estimated channel vector. The strongest chip-sample can be chosen and provided to the respective filter.

It can also be possible to select the chip-sample such that the strongest sample taken from each received chip interval is selected for filtering. This may give the best performance. Selectively choosing one of the chip-samples from one of the receiving antennas may be provided when either even or odd samples are used for filtering. The selection can be channel estimate based.

According to another embodiment, filtering the received signals with finite impulse response filtering (FIR) is provided.

To accomplish equalization of the signals from the respective transmission antennas, the equalization filters use the selected chip-samples from the reception antennas. The equalization filter for a certain transmission antenna can be considered to be split into a number of shorter filters, each of which filters only the selected chip-samples from a certain reception antenna. Equalized output for each chip interval is obtained by summing the outputs of each of these filters being dedicated to a particular transmission antenna. The summed signal represents the equalized output, which is an estimate of the signal that was transmitted from the particular transmission antenna.

To further allow demodulation of the received signals, the summed signal is provided to a dedicated correlator, for example a spreading code correlator. The demodulation is done according to the protocol used.

To allow decoding an STTD coded signal, providing the correlated summed signals to a space-time diversity decoder is also provided according to embodiments.

Another aspect of the invention is a system for transmitting and equalizing signals with at least one transmission antenna arranged for transmitting signals, at least one reception antenna arranged for receiving chip-samples of the transmitted signals, and equalizing means for filtering the received signals comprising filters assigned to a respective transmission antenna, which is characterized in that sample selection means are provided for selecting only one sample per chip for filtering within the respective filters.

Another aspect of the invention is a device for receiving and equalizing signals with at least one reception antenna arranged for receiving chip-samples of transmitted signal from at least one transmission antenna, and equalizing means for filtering each of the received signals comprising filters assigned to respective transmission antenna, which is characterized in that sample selection means are provided for selecting only one sample per chip for filtering within the respective filters.

A further aspect of the invention is a computer program and a computer program product for equalizing signals the program comprising instructions operable to cause a processor to receive within each of at least one reception antenna chip-sampled of a transmitted signal from at least one transmission antenna, equalize each of the received signals within filters assigned to a corresponding transmission antenna, which is characterized by filtering selectively the chip-samples of the received signals within filters assigned to the respective transmission antenna such that only one sample per chip is selected for filtering within the respective filters.

Other objects and features of the present invention will become apparent from the following detailed description considered in conjunction with the accompanying drawings. It is to be understood, however, that the drawings are designed solely for the purpose of illustration and not as a definition of the limits of the invention. It should be further understood that the drawings are not drawn to scale and that they are nearly intended to conceptually illustrate the structures and procedures describe herein.

### BRIEF DESCRIPTION OF THE DRAWINGS

In the Figures show:

FIG. 1 a conventional two receiver antenna chip-equalizer for 1-antenna transmission;

FIG. 2 a conventional two-reception antenna STTD equalizer;

FIG. 3 a block diagram of an inventive equalizer;

FIG. 4 a further block diagram of an equalizer according to the invention;

FIG. 5 another block diagram of an equalizer according to the invention.

### DETAILED DESCRIPTION OF THE DRAWINGS

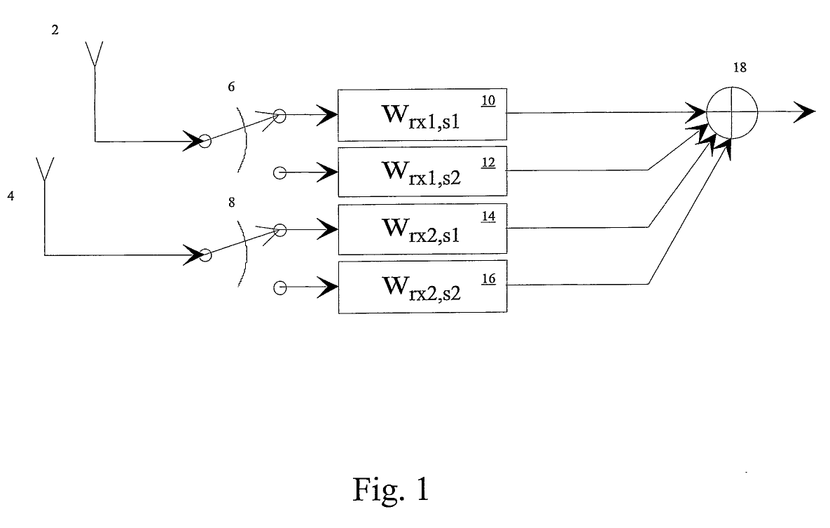

FIG. 1 depicts a conventional two reception antenna structure for one antenna transmission. This conventional FIR filter structure comprises two reception antennas 2, 4, and switches 6, 8 to provide the received chip-samples to one of the filters 10, 12, 14, 16 assigned to one of the reception antennas 2, 4.

The chip-equalizer structure according to FIG. 1 is designed for single-antenna transmission with two samples per chip. The four filters 10, 12, 14, 16 may, as well, be solved jointly by one single, long equalizer filter, split into four parallel chip-spaced filters.

It should be understood that splitting of the long equalizer filter into four chip-spaced filters 10, 12, 14, 16 is done only to illustrate different strategies of using the signal samples from different reception antennas, and it does not need to reflect the actual way of implementing the equalizer filter. This is true also with forthcoming equalizer structures.

Assuming two samples per chip, each chip-sample S1, and S2, and each reception antenna 2, 4 (RX1 and RX2) has assigned a particular filter 10, 12, 14, 16. The filters may be determined from the denotations W_{RxN, SN} with R_{xN} the number of the reception antenna and SN the number of the chip sample to be filtered. Reception antenna 2 has assigned the filters 10, 12, where filter 10 is assigned to chip-sample S1, and filter 12 is assigned to chip-sample S2. Switch 6 switches the received signals from reception antenna 2 between the filters 10, 12 for each chip-sample, respectively.

Reception antenna 4 has assigned the filters 14, 16. The switch 8 switches the received chip-samples for each chip-sample to the respective filter 14, 16. Filter 14 is assigned to chip sample S1, and filter 16 is assigned to chip sample S2.

The filtered signals for the received chip-samples are applied to an adder 18, where a summed signal is generated. Within the adder 18, for each chip-sample two signals from the respective antennas are summed. For a first chip-sample, the outputs of the filters 10, 14 are applied to adder 18, for the second chip-sample the outputs of the filters 12, 16 are applied to adder 18.

Within FIG. 1, equalizer filters 10, 12, 14, 16, which are coupled to respective reception antennas 2, 4 are provided. The filter outputs are summed together in adder 18. The depicted structure constitutes a basic equalizer, without showing radio frequency (RF), analog-to-digital converter (ADC) or other similar parts of the receiver. Using the switches 6 and 8 allows feeding the two samples, S1 and S2, during each chip interval to their respective filters. The selected chip-samples S1 and S2 are fed to two parallel chip-spaced FIR filters 10, 12 from reception antenna 2 and to chip-spaced FIR filters 14, 16 from reception antenna 4.

In general, using two samples per chip is the common way of implementing an equalizer. S1 denotes the first sample taken from each chip interval. S2 denotes the second chip sample taken from each chip interval. Insofar, the filter 10 filters a sample stream consisting of only the first (even) samples of each chip interval. Similarly, filter 12 filters a stream of second (odd) chip samples. The filter 14 again filters a sample stream consisting of only the first (even) samples of each chip interval. Similarly filter 16 again filters a stream of second (odd) chip samples. So the filters 10, 12 and 14, 16 can be called as chip-spaced or non-fractionally spaced filters. Any FIR filter using two samples per chip can be split into two parallel chip-spaced filters as shown in FIG. 1.

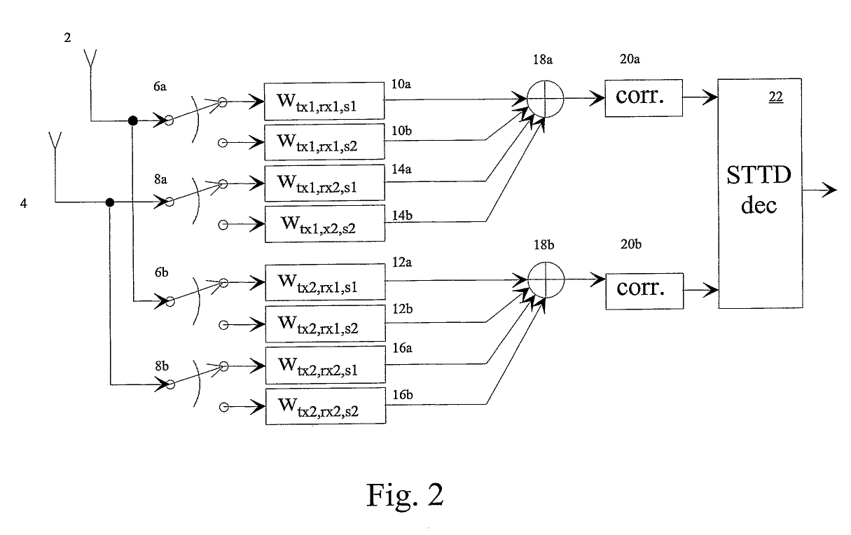

When applying two-antenna STTD transmission, a filter structure shown in FIG. 2 is conventionally necessary. FIG. 2 shows reception antennas 2, 4, switches 6a, b, 8a, b, filters 10a, b, 14a, b, 12a, b, 16a, b, adders 18a, b, correlators 20a, b, and STTD decoder 22. Equalized output signals are realized at the output of adders 18a, b.

As can be seen from FIG. 2, two parallel equalizers for each transmission antenna are required. It is possible to use two transmission antennas for transmitting the signal. For a first transmit antenna, the filters 10a, lob are assigned to reception antenna 2, and filters 14a, b are assigned to reception antenna 4. For the second transmission antenna, the filters 12a, 12b are assigned to reception antenna 2, and filters 16a, b are assigned to reception antenna 4. For received signals with two samples per chip one particular filter is necessary and provided for each chip-sample, each reception antenna and each transmission antenna. The filters are denoted with T_{xN}, R_{xM}, Sₒ, with N the number of the transmission antenna, M the number of the reception antenna, and O the index of the chip-sample. Having two chip-samples, two transmission antennas and two reception antennas results in having eight equalizer filters necessary.

The filter structure depicted in FIG. 2 doubles the filtering complexity. An STTD equalizer suitable for 2-antenna HSDPA transmission protocols requires a multiplication rate for the filters 10-16 of 2.6 GHz, even though STTD might be used in praxis only rarely.

FIG. 2 is an equalizer for an STTD transmitted signal. As can be seen, each one of two STTD transmission antennas (denoted by Tx1 and Tx2) needs its own equalizer. In case of two samples per chip, the sample stream having 2 samples per chip from each Rx antenna may be split into two parallel streams. Each of these sample streams is filtered by its own chip-spaced filter. E.g. Filters 10a and 10b filter the sample streams S1 and S2 from Rx1, respectively. Compared to FIG. 1, the filtering complexity is doubled.

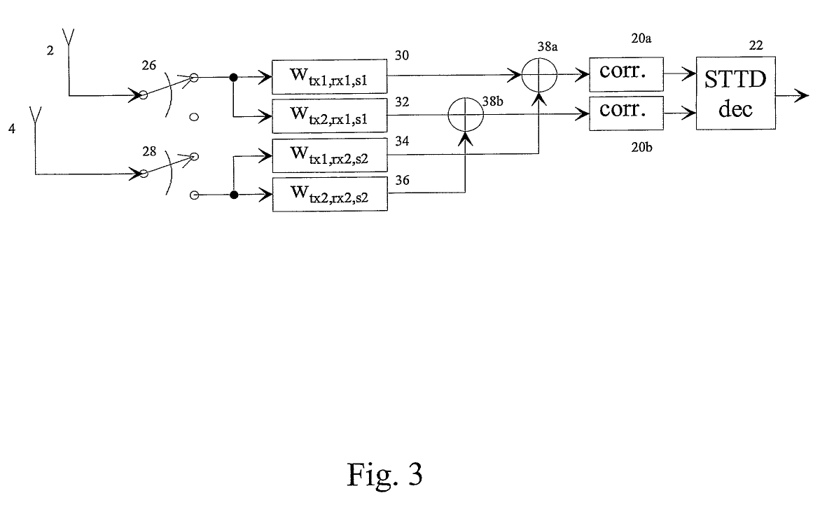

FIG. 3 shows a filter structure according to the invention. This structure halves the filtering complexity. The FIR filters 30-36 used for equalization of 1-antenna transmission may as well be used for STTD transmission, if required. Shown are reception antennas 2, 4, switches 26, 28, filters 30, 32, 34, 36, adder 38a, b, correlators 20a, b and STTD decoder 22. A conventional equalizer using at least two samples per chip and configured for single-antenna transmission can be reconfigured to use only one sample per chip within transmissions with at least two transmission antennas.

The proposed structure uses only one sample per chip from reception antenna 2, and one sample per chip from reception antenna 4. Different chip-samples from different reception antennas 2, 4 can be applied to the filters 30-36. The switches 26, 28 demultiplex the chip-samples into two sample streams and allow selecting, which chip-samples are used from each reception antenna in the filters. In this configuration, one of the two chip-samples remain unused in the equalizer filters.

In the shown position, switch 26 provides the chip sample of reception antenna 2 to the filters 30, 32. The filters 30, 32 are assigned to transmission antenna one and two. Thus, chip sample one is filtered by each of the transmission antennas. The current chip sample from reception antenna 4 is not used, as switch 28 is in an off position.

In the position opposite to the depicted one, filter 28 applies the respective chip-sample from reception antenna 4 to the filters 34, 36, and switch 26 cuts off filters 30, 32 from reception antenna 2.

For instance, when alternating the positions of the switches 26, 28 for each chip-sample interval, each first chip-sample from reception antenna 2 may be applied to the filters 30, 32 and each second chip-sample from reception antenna 4 may be applied to the filters 34, 36. The chip-samples transmitted from transmit antenna one are equalized within filters 30, 34 and de-spread in correlator 20a, and the chip-samples from transmit antenna 2 are equalized within filters 32, 36 and de-spread in correlator 20b. Each of the filters 30, 32, 34, 36 is applied with one of two consecutive chip-samples. An unfavourable sample-timing in one antenna may be compensated for by a favourable sample-timing in the other antenna, which may reduce the loss compared to two-samples-per-chip-case.

The correlator 20a is applied with a summed signal from transmission antenna one for consecutive chip-samples, which are summed by adder 38. The correlator 20b is applied with a summed signal of adder 38b, which sums consecutive chip-samples of transmission antenna two. The output of the correlators 20a, b is provided to STTD decoder 22 and the resulting signal is further processed.

FIG. 3 shows a simple fixed selection scheme where the first chip samples are used from reception antenna 2 and the second chip samples are used from reception antenna 4. Another approach may be to select the used chip-samples based on which sample carries more energy of the desired signal component so that the performance loss is minimized.

A further option of selecting the chip samples to provide only one sample per chip to an equalizer of a reception antenna may be to provide a sample combiner block which combines, e.g. sums, the two chip-samples of a reception antenna prior to the equalization.

The inventive embodiments allow reconfiguring an equalizer for 1-antenna transmission as depicted in FIG. 1 into a structure as shown in FIGS. 3-5, in particular when an STTD signal has to be equalized.

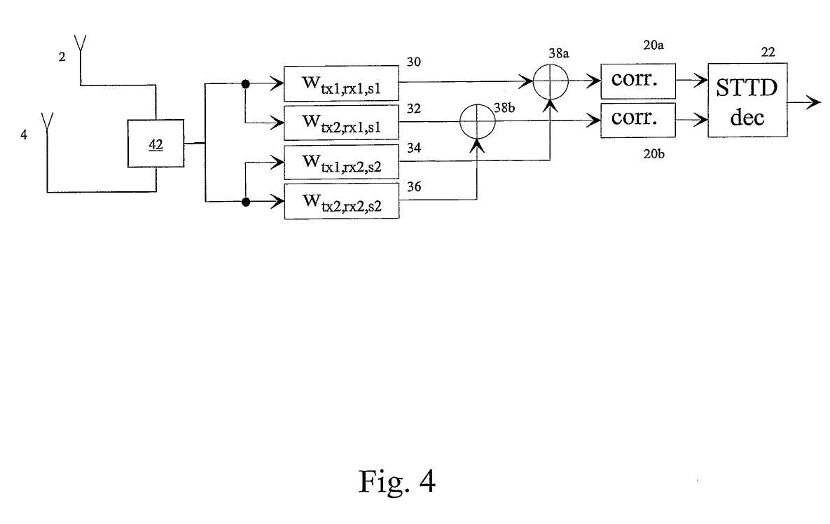

Another possible solution is depicted in FIG. 4. FIG. 4 comprises similar elements as FIG. 3 with similar functionality. The switches 26, 28 are replaced by device 42. Within device 42, the even and odd chip-samples received from reception antennas 2, 4 are compared with each other in terms of total energy of the estimated channel vector. The strongest chip-sample is chosen and provided to the respective filters.

For instance, if the chip-sample from reception antenna 2 is stronger than the chip-sample from the reception antenna 4, this chip-sample is applied to the filters 30, 32. On the other hand, if the chip sample from received antenna 4 is stronger than the chip sample from reception antenna 2, device 42 provides this chip-sample to filters 34, 36. Further processing of the signals is according to FIG. 3.

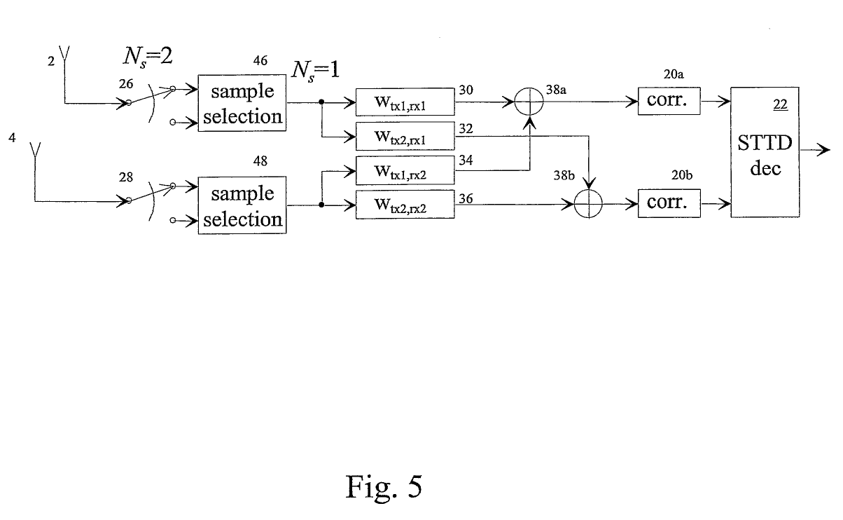

FIG. 5 depicts an assembly which may also be used in the application. Same reference numbers refer to same elements with similar functionality. Ns denotes number of samples per chip. In the depicted case, each reception antenna 2,4 provides two samples per chip. The benefit from using two antennas all the time comes from the fact that noise is uncorrelated in the antennas while consequent chip samples are strongly correlated so it is safe to use only one of them.

STTD requires an equalizer for each transmission antenna. However, the equalization complexity may be reduced by using only one sample per chip in the equalizers. Compared to FIG. 1, FIG. 5 shows an assembly with a similar structure as used with 1-antenna transmission. However, by using the sample selection means 46, 48, only one sample per chip may be selected. The resulting signal with only one sample per chip may be provided to the equalizers. The samples which are not used may be discarded.

The inventive method, system, device, computer program and use allow configuring an 1-antenna transmission design to be used also for STTD equalization. The STTD equalizer FIR filter complexity may be reduced by 50%. The multiplication rate for equalization may be 1.3 GHz and no extra processing power needs to be reserved for STTD equalization. The filter time-span in terms of number of chips may remain the same for the equalizers even for STTD equalization. Insofar the capability of equalizing long channels like PedB channels with a filter-time-span of 21 chips may not be compromised. The number of filters may be reduced and the number of channel paths to be estimated may also be reduced. The channel estimator used for 1-antenna transmission systems may be re-used also for STTD transmission.

While there have been shown and described and pointed out fundamental novel features of the invention as applied to a preferred embodiment thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1. Method, comprising
receiving within each of at least one reception antenna chip samples of signals transmitted from at least two transmission antennas,
reconfiguring equalizer filters arranged for at least two samples per chip and for 1-antenna transmission into equalizer filters arranged for at least 2-antenna transmission, and
equalizing the received signals within the reconfigured equalizer filters by filtering selectively the chip-samples of the received signals within the equalizer filters assigned to the respective transmission antenna such that only one sample per chip is selected for filtering within the respective equalizer filters.

2. Method of claim 1, with filtering selectively the chip-samples such that the chip-samples are chosen from the reception antennas in an alternating order.

3. Method of claim 1, with receiving the transmitted signal within the at least one reception antenna and filtering selectively the chip-samples such that the chip-samples are chosen from the reception antennas based on the relative energy of the received signal.

4. Method of claim 3, with filtering selectively the chip-samples such that the strongest sample taken from each received chip interval is selected for filtering.

5. Method of claim 1, with filtering the received signals with finite impulse response filtering.

6. Method of claim 1, with adding the outputs of filters connected to different reception antennas and dedicated to corresponding transmission antennas into summed signals.

7. Method of claim 6, with providing the summed signals of output filters to a dedicated correlator.

8. Method of claim 7, with providing the correlated summed signals to a space time diversity decoder.

9. System for transmitting and equalizing signals with
at least two transmission antennas arranged for transmitting signals,
at least one reception antenna each arranged for receiving chip-samples of the transmitted signals,
equalizers arranged for at least two samples per chip and for 1-antenna transmission are reconfigured into equalizers arranged for at least 2-antenna transmission and for filtering the received signals within equalizer filters assigned to a respective transmission antenna, and
samplers provided for selecting only one sample per chip for filtering within the respective equalizer filters.

10. Device, comprising
at least one reception antenna arranged for receiving chip-samples of transmitted signal from at least two transmission antennas;
equalizers arranged for at least two samples per chip and for 1-antenna transmission and reconfigured into equalizers arranged for at least 2-antenna transmission and for filtering the received signals within equalizer filters assigned to a respective transmission antenna; and
samplers provided for selecting only one sample per chip for filtering within the respective equalizer filters.

11. Computer program embodied in a computer readable medium for equalizing signals, the program comprising instructions for
receiving within each of at least one reception antenna chip-samples of a transmitted signal from at least two transmission antennas,
reconfiguring equalizers arranged for at least two samples per chip and for 1-antenna transmission into equalizers arranged for 2-antenna transmission, and
filtering selectively the chip-samples of the received signals within equalizer filters assigned to the respective transmission antenna such that only one sample per chip is selected for filtering within the respective equalizer filters.

12. Apparatus, comprising
means for receiving within each of at least one reception antenna chip samples of signals transmitted from at least two transmission antennas;
means for reconfiguring equalizer filters arranged for at least two samples per chip and for 1-antenna transmission into equalizer filters arranged for at least 2-antenna transmission; and
means for equalizing the received signals within the reconfigured equalizer filters by filtering selectively the chip-samples of the received signals within the equalizer filters assigned to the respective transmission antenna such that only one sample per chip is selected for filtering within the respective equalizer filters.

13. Device of claim 10, with filtering selectively the chip-samples such that the chip-samples are chosen from the reception antennas in an alternating order.

14. Device of claim 10, with receiving the transmitted signal within the at least one reception antenna and filtering selectively the chip-samples such that the chip-samples are chosen from the reception antennas based on the relative energy of the received signal.

15. Device of claim 14, with filtering selectively the chip-samples such that the strongest sample taken from each received chip interval is selected for filtering.

16. Method of claim 10, with filtering the received signals with finite impulse response filtering.

17. Device of claim 10, with adding the outputs of filters connected to different reception antennas and dedicated to corresponding transmission antennas into summed signals.

18. Device of claim 17, with providing the summed signals of output filters to a dedicated correlator.

19. Device of claim 18, with providing the correlated summed signals to a space time diversity decoder.
